(19) United States
(12) Patent Application Publication
(10) Pub. No.: US 2018/0185893 A1
(43) Pub. Date: Jul. 5, 2018

(54) SYSTEMS, METHODS, AND APPARATUS FOR TRANSFER CHAMBER GAS PURGE OF ELECTRONIC DEVICE PROCESSING SYSTEMS

(71) Applicant: Applied Materials, Inc., Santa Clara, CA (US)

(72) Inventor: Joseph Vincent, Bangalore (IN)

(21) Appl. No.: 15/396,637

(22) Filed: Dec. 31, 2016

(51) Int. Cl. B08B 9/08; H01L 21/67; B08B 5/00; B05B 1/34

(52) U.S. Cl. CPC B08B 9/08; B05B 1/34; B08B 5/00; H01L 21/67196

(57) ABSTRACT

Transfer chamber gas purge systems, apparatus, and methods are disclosed. Embodiments include a transfer chamber including a plurality of distributed purge gas inlets, each inlet including a diffusing member, each diffusing member including a diffusing element and a diffusing housing integrally formed as a single piece. The diffusing element and the diffuser housing together form a diffusing chamber configured to cause a purge gas exiting the porous diffusing element to have a laminar flow. Numerous other aspects are disclosed.

### FIELD

The present invention relates to electronic device processing systems, and more specifically to transfer chamber gas purge apparatus, systems, and methods including vent gas diffusing members for use therein.

### BACKGROUND

Conventional electronic device manufacturing systems may include one or more process chambers that are adapted to carry out any number of processes, such as degassing, cleaning or pre-cleaning, deposition such as chemical vapor deposition (CVD), physical vapor deposition (PVD), or atomic layer deposition, coating, oxidation, nitration, etching (e.g., plasma etch), or the like. One or more load lock chambers may be provided to enable entry and exit of substrates from an equipment front end module (EFEM) (sometimes referred to as a factory interface (FI)). Each of these process chambers and load lock chambers may be included in a cluster tool, where a plurality of process chambers may be distributed about a transfer chamber, for example. A transfer robot may be housed within the transfer chamber to transport substrates to and from the various process chambers and load locks on one or more end effectors. Conventionally, a slit valve opening is provided between the transfer chamber and each process chamber and load lock chamber. One or more end effectors (e.g., blades) of the transfer robot may pass through the slit valve opening to place or extract a substrate (e.g., a silicon wafer, glass plate, or the like) into or from a support (e.g., a pedestal or lift pins) provided within the process chamber or load lock chamber.

Once the substrate is properly disposed within the process chamber, the slit valve may be closed, and the processing of the substrate may commence. As part of the processing, particles may be formed due to moving components in the system. If such particulates come to rest on the processed substrates, this may impact the quality of the substrate. To minimize particulates, prior systems have included a gas inlet into the transfer chamber underneath the robot as well as a gas exit out of the transfer chamber, also under the robot to accomplish purge of the transfer chamber. However, such systems have been generally ineffective.

Accordingly, improved transfer chamber gas flow apparatus, systems, and methods are desired.

### SUMMARY

In some embodiments, a vent gas diffusing member is provided. The vent gas diffusing member includes a diffusing element and a diffusing housing integrally formed as a single piece. The diffusing element and the diffuser housing together form a diffusing chamber configured to cause a purge gas exiting the porous diffusing element to have a laminar flow.

In other embodiments, an electronic device processing system is provided. The electronic device processing system includes a transfer chamber including a plurality of distributed purge gas inlets, each inlet including a diffusing member, each diffusing member including a diffusing element and a diffusing housing integrally formed as a single piece. The diffusing element and the diffuser housing together form a diffusing chamber configured to cause a purge gas exiting the porous diffusing element to have a laminar flow.

In yet other embodiments, a method of purging a transfer chamber is provided. The method includes providing a transfer chamber; and purging the transfer chamber by inflow of a purge gas through a plurality of distributed inlets in the chamber lid, the inlets include a diffusing member, each diffusing member including a diffusing element and a diffusing housing integrally formed as a single piece. The diffusing element and the diffuser housing together form a diffusing chamber configured to cause a purge gas exiting the porous diffusing element to have a laminar flow.

Numerous other features are provided in accordance with these and other aspects of the invention. Other features and aspects of embodiments of the present invention will become more fully apparent from the following detailed description, the appended claims and the accompanying drawings.

### BRIEF DESCRIPTION OF THE DRAWINGS

FIG. 1A illustrates a schematic top view of an electronic device processing system including transfer chamber gas purge apparatus according to embodiments.

FIG. 1B illustrates a cross-sectioned partial side view of an electronic device processing system including transfer chamber gas purge apparatus according to embodiments.

FIG. 2 illustrates a cross-sectioned partial side view of a chamber inlet including a vent gas diffusing member of a gas purge apparatus according to embodiments.

FIG. 3 illustrates a top view of a chamber lid including vent gas diffusing members of a gas purge apparatus according to embodiments.

FIG. 4 illustrates a partial cross-sectioned side view of a first example vent gas diffusing member according to embodiments.

FIG. 5 illustrates a partial cross-sectioned side view of a second example vent gas diffusing member according to embodiments.

FIG. 6 illustrates a partial cross-sectioned side view of a third example vent gas diffusing member according to embodiments.

FIG. 7 a flowchart depicting a method of using a vent gas diffuser according to embodiments.

FIGS. 8 through 10 are flowcharts, each depicting an alternative example method of manufacturing a vent gas diffusing member according to embodiments.

### DESCRIPTION

Existing electronic device manufacturing systems have used purge within a transfer chamber in an attempt to control particulates. In particular, prior art purge systems have included an inlet and an outlet in a floor of the transfer chamber. Although some improvement is provided by this type of transfer chamber purge, additional measures to control particulates are desired in order to further improve system/tool yield. Embodiments disclosed herein use improved vent gas diffusing members that can be formed in whole or in part using 3D printing methods to minimize the amount of chamber wall “real-estate” used for purge gas inlets. Further, embodiments provide improved ability to integrate a porous filter membrane with the housing of the vent gas diffusing member.

Embodiments further provide improved transfer chamber gas purge apparatus, systems, and methods. In some aspects, an improved transfer chamber gas purge apparatus is provided that includes the improved vent gas diffusing members. The transfer chamber gas purge apparatus is useful for purging a transfer chamber adapted to contain at least a portion of a transfer robot which is adapted to carry one or more substrates. The transfer chamber includes side walls, a chamber lid, and a chamber floor. The chamber lid has a plurality of distributed chamber inlets therein.

In one or more embodiments, some or all of the plurality of distributed chamber inlets may include vent gas diffusing members adapted and functional to diffuse inlet purge gas flow. Furthermore, a plurality of distributed chamber outlets may be including in the chamber floor. In further embodiments, the plurality of distributed chamber inlets may include primary chamber inlets and secondary inlets. Such primary chamber inlets and secondary inlets may be independently controllable in some embodiments. Thus, improved transfer chamber purge is provided, especially in an area of the transfer chamber where the substrate(s) are positioned when being transferred through the transfer chamber. In some embodiments, laminar purge gas flow is provided above the substrate(s).

In another aspect, an electronic device processing system is provided. The electronic device processing system includes a transfer chamber adapted to contain at least a portion of a robot carrying a substrate, wherein the transfer chamber includes a chamber lid, side walls, and a chamber floor, a plurality of distributed chamber inlets provided in the chamber lid, and a plurality of distributed chamber outlets included the chamber floor.

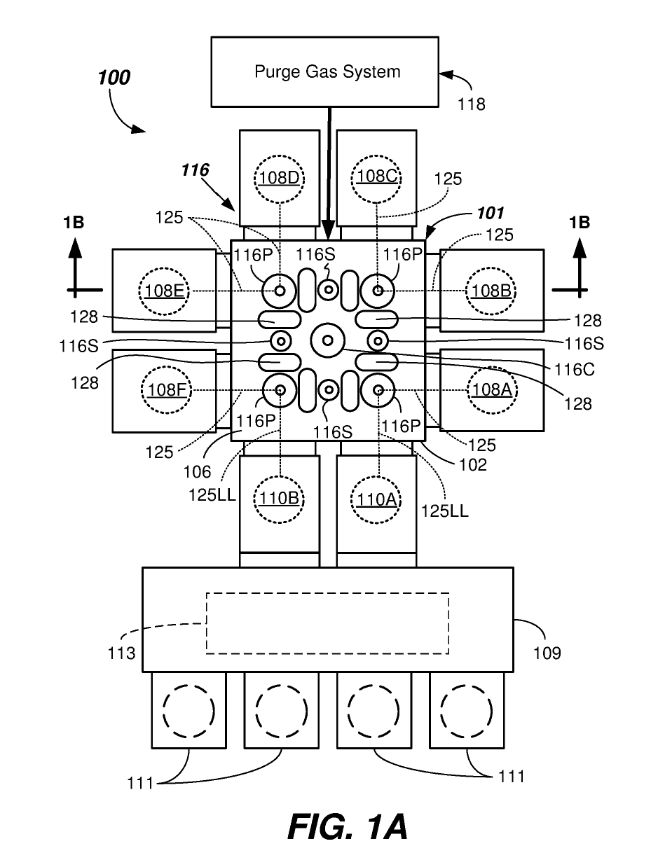

Further details of example embodiments illustrating and describing various aspects of the invention, including apparatus, systems, and method aspects, are described with reference to FIGS. 1A-7 herein.

FIGS. 1A and 1B illustrate a top schematic view and a cross-sectional side view, respectively, of an example embodiment of an electronic device processing system 100 including a transfer chamber gas purge apparatus 101. The electronic device processing system 100 may be adapted to process substrates (e.g., silicon-containing wafers, plates, discs, or the like) by imparting one or more processes thereto, such as degassing, cleaning or pre-cleaning, deposition such as chemical vapor deposition (CVD), physical vapor deposition (PVD), or atomic layer deposition (ALD), coating, oxidation, nitration, etching (e.g., plasma etch), or the like. Other processes may be carried out by the electronic device processing system 100.

The depicted electronic device processing system 100 includes a mainframe housing 102 including a transfer chamber 103 formed at least by side walls 104, a chamber lid 106, and chamber floor 107 thereof. A plurality of process chambers 108A-108F and one or more load lock chambers 110A, 110B may be mechanically coupled to the mainframe housing 102. Other numbers of process chambers and load lock chambers may be included. The transfer chamber 103 includes a robot 112 that is configured and adapted to transfer one or more substrates 114 to and from at least two chambers that are coupled to the mainframe housing 102. The at least two chambers are accessible by the robot 112, and at least a part of the robot 112 resides in the transfer chamber 103. As used herein, a “transfer chamber” contains at least a portion of a robot 112 (e.g., moving arms and an attached end effector 112E) that is adapted to transport one or more substrates 114 to and from chambers (e.g., process chambers 108A-108F) accessed from the transfer chamber 103. The electronic device processing system 100 may also include an EFEM 109 having one or more substrate carriers 111 docked thereto. Substrate carriers 111 are adapted to carry one or more substrates 114 within the manufacturing environments (e.g., between tools). An EFEM robot 113 (shown as a dotted box) may be included in the EFEM 109 in one or more embodiment, and may function to transfer substrates 114 between the substrate carriers 111 and the one or more load lock chambers 110A, 110B.

In the depicted embodiment, the robot 112 may include arms 112A, 112B, 112C inside of the transfer chamber 103, one or more robot motors 112M, which may be outside of the transfer chamber 103, and one or more end effectors 112E upon which substrates 114 may rest and be transported. End effectors 112E may be rigidly coupled together or may be independently actuated. Robot 112 may be of any suitable construction, such as described in U.S. Pat. Nos. 5,789,878; 5,879,127; 6,267,549; 6,379,095; 6,582,175; and 6,722,834; and US Pat. Pub. Nos. 2010/0178147; 2013/0039726; 2013/0149076; 2013/0115028; and 2010/0178146, for example. Other suitable robots may be used.

Robot 112 is operable to transport substrates 114 to and from the process chambers 108A-108F and to and from the one or more load lock chambers 110A, 110B. In each case, the transfer is through an opening 115 (e.g., slit valve opening) formed in the mainframe housing 102, generally a slit-shaped opening, which may have a slit valve door (not shown) operable therewith to seal the respective chambers after the substrate 114 has been placed therein by the robot 112. In the depicted embodiment, twinned, that is side-by-side chambers are provided. However, it should be understood that the transfer chamber gas purge apparatus 101 may be used with other transfer chamber configurations, such as those including radially-accessed process chambers included in heptagonal, hexagonal, or octagonal mainframe housings, or the like. Other shapes of the transfer chamber 103 may be used.

As previously discussed, the transfer chamber gas purge apparatus 101 includes the transfer chamber 103 adapted to contain at least a portion of the robot 112, the transfer chamber 103 being at least partially formed by the interconnection of side walls 104, a chamber lid 106, and a chamber floor 107. In the depicted embodiment, the chamber lid 106 has a plurality of distributed chamber inlets 116 therein, which may include primary chamber inlets 116P and secondary chamber inlets 116S. Chamber inlets 116 are coupled to a purge gas supply assembly 118. Purge gas supply assembly 118 may include a purge gas source 120, such as a pressurized gas-containing vessel, a flow control assembly 122, which may comprise one or more valves or mass flow controllers adapted to control purge gas flow, and a controller 123.

The purge gas supply assembly 118 may also include an intake manifold 124, which may be a collection of gas flow pathways (e.g., conduits) that are coupled between the flow control assembly 122 and the plurality of chamber inlets 116. Intake manifold 124 may include primary pathways 124P and secondary pathways 124S. Purge gas flow through the primary pathways 124P and secondary pathways 124S may fluidly couple to the primary and secondary chamber inlets 116P, 116S, so that purge gas flow to the primary chamber inlets 116P and secondary chamber inlets 116S may be independently controllable by the flow control assembly 122. Purge gas may comprise an inert gas, such as N₂. Other suitable purge gases may be used. In some embodiments, the transfer chamber 103 may be maintained at a vacuum, for example.

Chamber lid 106 may be at the top of the transfer chamber 103 and located generally above the level of the end effectors 112E and supported substrates 114. Chamber lid 106 may be removable and may connectable to the side walls 104 in some alternative embodiments.

In the depicted embodiment, the plurality of distributed chamber inlets 116 on the chamber lid 106 includes four primary chamber inlets 116P located in the transfer chamber 103. At least some of the primary chamber inlets 116P may be positioned above a transfer path of the substrate 114 as it exits the respective process chamber 108A-108F. For example, one or more of the primary chamber inlets 116P may be positioned above transfer paths 125. In this manner, purge gas may flow downwardly and over the substrate 114, blanketing the substrate 114 with purge gas flow as the substrate 114 exits the respective process chambers 108A-108F.

Similarly, primary chamber inlets 116P may be positioned above load lock transfer paths 125LL of the one or more substrates 114 as they enter into the transfer chamber 103 from the load lock chambers 110A, 110B. In twinned transfer chamber configuration shown in FIGS. 1A and 1B, positioning of the plurality of distributed chamber inlets 116 may serve to provide improved purge gas flow as the substrates 114 exit from the process chambers 108A-108F.

The plurality of distributed chamber inlets 116 of the transfer chamber gas purge apparatus 101 may include at least four secondary chamber inlets 116S. At least some of the secondary chamber inlets 116S may be arranged between respective ones of the primary chamber inlets 116P. For example, the secondary chamber inlets 116S may be arranged to purge the transfer chamber volume located between the openings 115, or between the openings to the load lock chambers 110A, 110B. An optional primary or secondary inlet 116C may be provided at or near a physical center of the transfer chamber 103, as shown. In some embodiment, a plurality of view windows 128 (a few labeled) may be formed in the chamber lid 106. View windows 128 may include clear or translucent panels, such as glass panels and may allow the robot 112 and components thereof as well as the substrates 114 to be viewed within the transfer chamber 103. View windows 128 may be arranged between the respective primary and secondary chamber inlets 116P, 116S.

In one or more embodiments, the transfer chamber gas purge apparatus 101 may include a plurality of chamber outlets 126. Plurality of chamber outlets 126 may exit from the chamber floor 107. However, the plurality of chamber outlets may exit from the side walls 104 (e.g., at the bottom of the side walls 104) in some embodiments. In the depicted embodiment, the plurality of chamber outlets 126 exit from the chamber floor 107 of the transfer chamber 103 at a location below the substrates 114. The plurality of chamber outlets 126 may couple to an exhaust manifold 127 that is adapted to flow the purge gas exiting the transfer chamber 103 to an exhaust system, such as a factory exhaust. Exhaust manifold 127 may be arranged around the robot motor 112M. One or more vacuum sources 129, such as vacuum turbo pumps, may be coupled to the exhaust manifold 127 to provide a desired level of vacuum in the transfer chamber 103 during the purge process in some embodiments. In some embodiments, the location of one or more of the plurality of chamber outlets 126 may be positioned vertically in line with one or more of the plurality of chamber inlets 116 (e.g., see dotted vertical line in FIG. 1B connecting primary chamber inlets 116P and the chamber outlets 126). For example, in the depicted embodiment, four chamber inlets 116P lie directly vertically above four chamber outlets 126. In other embodiments, at least some of the plurality of chamber outlets 126 may be positioned radially in line (lie along a same radius) with one or more of the plurality of chamber inlets 116.

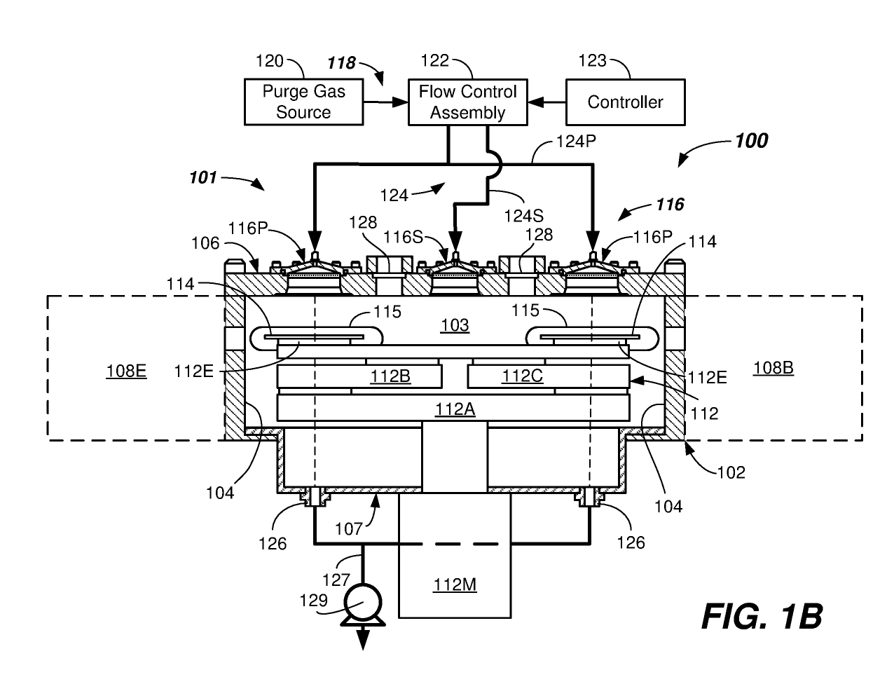

In the depicted embodiments, the chamber inlets 116 (e.g., chamber inlets 116P, 116S, 116C shown) may include a diffusing member 229 including a diffusing element 230 and a diffuser housing 231. An example chamber inlet 116P including a diffusing member 229 is shown in FIG. 2. The diffusing element 230 may include a metal disk or cylinder-shaped, porous membrane having an enlarged frontal or side surface area as compared to a cross-sectional area of the primary pathway 124P of the intake manifold 124 that is coupled to the chamber inlet 116P. In the depicted embodiment, the diffusing element 230 may include a porous metal disk. Diffusing member 229 also includes a diffuser housing 231 at least partially forming a diffusing chamber 232 that receives a purge gas from the primary pathway 124P of the intake manifold 124 and enlarges in cross-sectional area to pass the purge gas through an enlarged entry area on an entry side of the diffusing element 230. Purge gas then passes through the diffusing element 230 (e.g., through open pores thereof) and may pass into an expansion zone 234 which may be formed in the chamber lid 106 and located downstream of the diffusing element 230. Within the expansion zone 234, the purge gas flow transitions into the transfer chamber 103. Expansion zone 234 may include one or more frusto-conical sections or a radius, for example. In the depicted example, the expansion zone 234 includes interconnected frustocone sections having different cone angles. Other area-enlarging transition zone structures may be used.

In one or more embodiments, the plurality of distributed chamber inlets 116 may include primary chamber inlets 116P and secondary chamber inlets 116S having different inlet flow areas at their respective entrances into the transfer chamber 103 (See FIG. 1B). In particular, the area of the primary chamber inlets 116P may be larger than the area of the secondary chamber inlets 116S in some embodiments. For example, the area of each of the primary chamber inlets 116P and the secondary chamber inlets 116S may be between about 10 cm² and between about 100 cm². However, other sizes may be used. Furthermore, in some embodiments, the secondary chamber inlets 116S may be equal in size to the primary chamber inlets 116P.

As is conventional, substrates 114 may be provided to, and withdrawn from, the process chambers 108A-108F through openings 115 (e.g., slit valve openings). A general level of vacuum may be provided in the transfer chamber 103 by an operation of one or more vacuum sources 129 (e.g., one or more turbo pumps) connected below the chamber outlets 126.

Operation of the transfer chamber gas purge apparatus 101 may be adjusted via control signals to the flow control assembly 122 from a controller 123 to provide a laminar gas flow pattern above the substrate 114. Gas flow adjustments may be made by adjusting the overall flow rate of the purge gas from the purge gas source 120 to the plurality of chamber inlets 116. In particular, purge gas flow adjustments may be made by adjusting the flow control assembly 122. Flow control assembly 122 may comprise one or more valves, mass flow controllers (MFC's), or other suitable gas flow adjusters. In particular, purge gas flow provided to the primary and secondary chamber inlets 116P, 116S may be independently controlled by controlling flow control members (valves, MFC's or the like) of the flow control assembly 122, for example.

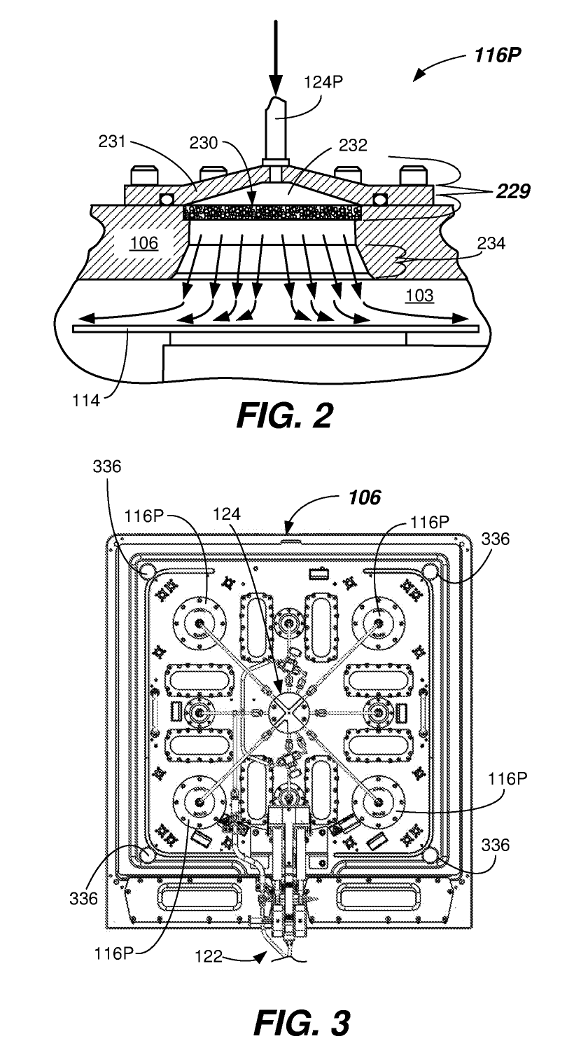

FIG. 3 illustrates a top view of an example of a chamber lid 106 including an intake manifold 124 and flow control assembly 122 coupled thereto. Chamber lid 106 may be removable from the mainframe housing 102 and secured thereto by fasteners. Sealing between the bottom of the chamber lid 106 and the mainframe housing 102 may be provided by suitable O-ring or other sealing member. In some embodiments, the chamber lid 106 may be pivotal and lifted by lift pins 336.

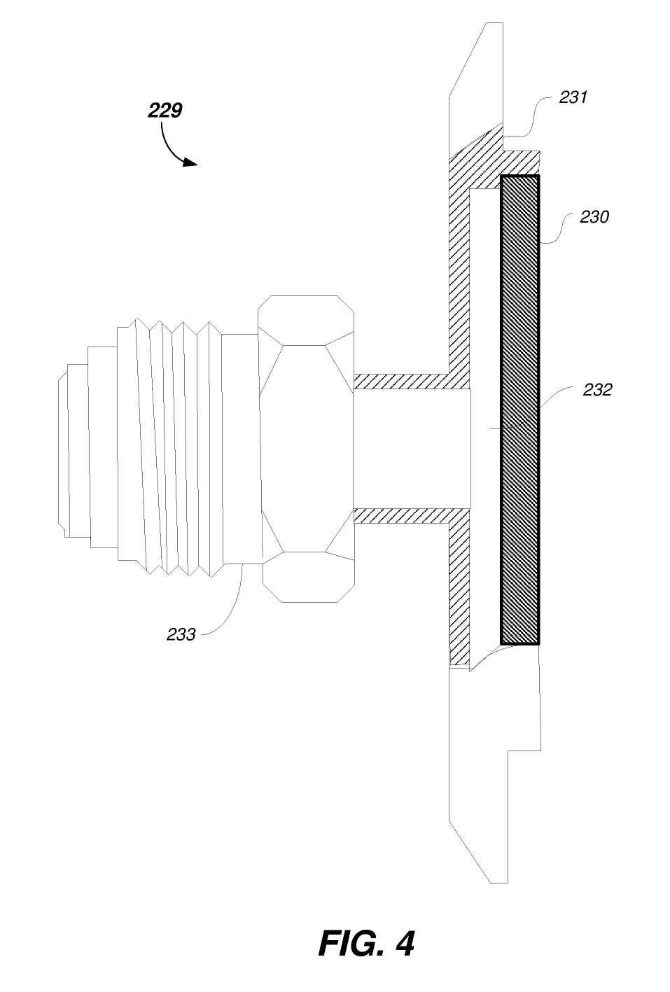

FIG. 4 illustrates a magnified partial cross-sectional side view of an example diffusing member 229. The diffusing member 229 includes a diffusing element 230 that can function as both a filter and a diffuser to improve the laminar flow of the purge gas flowing out of the diffusing chamber 232 (formed by the diffuser housing 231 and the diffusing element 230), into the transfer chamber 103. The diffusing member 229 can also include a coupling 233 for attachment to the intake manifold 124.

Embodiments of the diffusing member 229 can be manufactured by metal additive manufacturing processes using any practicable material that can be 3D printed (e.g., using Selective Laser Melting (SLM), Laser Cusing, Direct Metal Laser Sintering (DMLS), and/or Electron Beam melting (EBM) processes in, for example, metal powder bed fusion machines, laser cladding machines, directed energy deposition machines and laser metal deposition machines). In some embodiments, the design uses 316L stainless steel material, other stainless steels, aluminum, nickel, cobalt-chrome, and titanium alloys. Use of other materials is possible.

In the embodiment shown in FIG. 4, the diffusing member 229, including the diffuser housing 231 portion and the diffusing element 230 portion, is printed as a single integrated part, formed in a single printing process. In this embodiment, the diffuser housing 231 portion is printed solid and the diffusing element 230 portion is printed porous. Even though the two portions are printed with different densities, the two portions are integrally formed together as a single piece. In other words, the diffusing element 230 portion is an integrally formed part of the diffuser housing 231 portion, both printed together as a single part wherein the diffuser housing 231 portion of the diffusing member 229 is printed solid and the diffusing element 230 is printed with porosity (e.g., with numerous holes of a particular shape) to be able to trap or block particles greater than approximately 0.003 microns. The holes in the diffusing element 230 can be cylindrical, conical, rectangular, combinations thereof, or other shapes. In some embodiments, the porosity of the diffusing element 230 portion can be achieved by changing the 3D printing density parameter from solid (for the diffuser housing 231 portion) to porous (for the diffusing element 230 portion) for the material being used (e.g., stainless steel). In some embodiments, after printing, the surface of the diffuser housing 231 that seals against the transfer chamber 103 can be machined and polished to achieve a sufficiently smooth sealing surface.

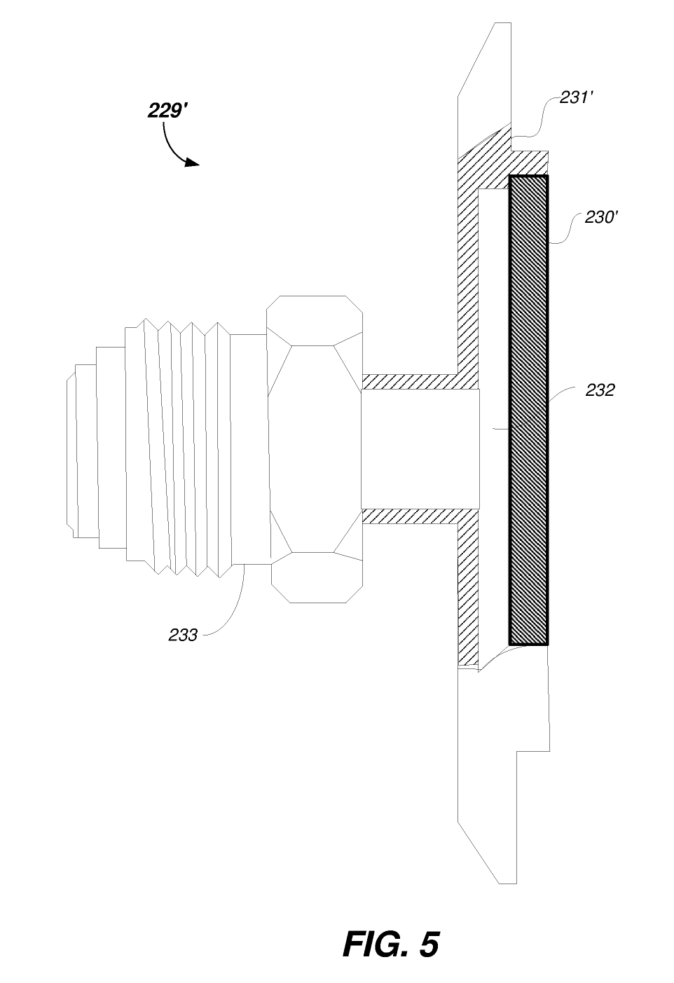

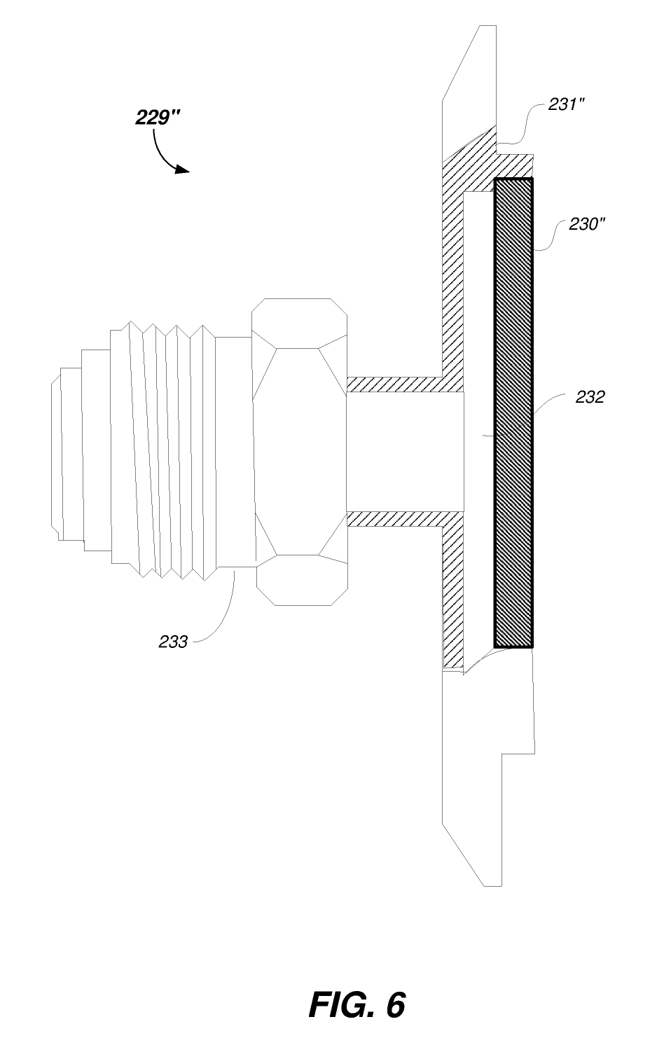

Turning now to FIGS. 5 and 6, two additional embodiments of a diffusing member 229′, 229″ are depicted. While the diffusing members 229, 229′, 229″ of FIGS. 4 through 6 look similar, the diffusing members 229, 229′, 229″ are each manufactured differently. Whereas the diffusing member 229 of FIG. 4 is 3D printed as a single integrally formed piece, the diffusing member 229′ of FIG. 5 is formed by welding (or otherwise coupling) a 3D printed porous diffusing element 230′ to a conventionally machined (e.g., milled) diffuser housing 231′ and the diffusing member 229″ of FIG. 6 is formed by welding (or otherwise coupling) a conventionally machined (e.g., sintered nickel) porous diffusing element 230″ to a 3D printed diffuser housing 231″.

By using 3D printed diffusing members, embodiments enable use of relatively inexpensive and easily customized inlets 116 that can more easily be located (e.g., relative to conventional inlets that use standard size diffusers) in any desired location on the transfer chamber 103 while using a minimum of chamber wall/lid area. Further, the customization of the shape and size of the diffusing member affords convenient customization of the diffusing chamber 232 as well as the gas flow path inside the diffusing member to provide a non-turbulent venting/purging of transfer chamber 103.

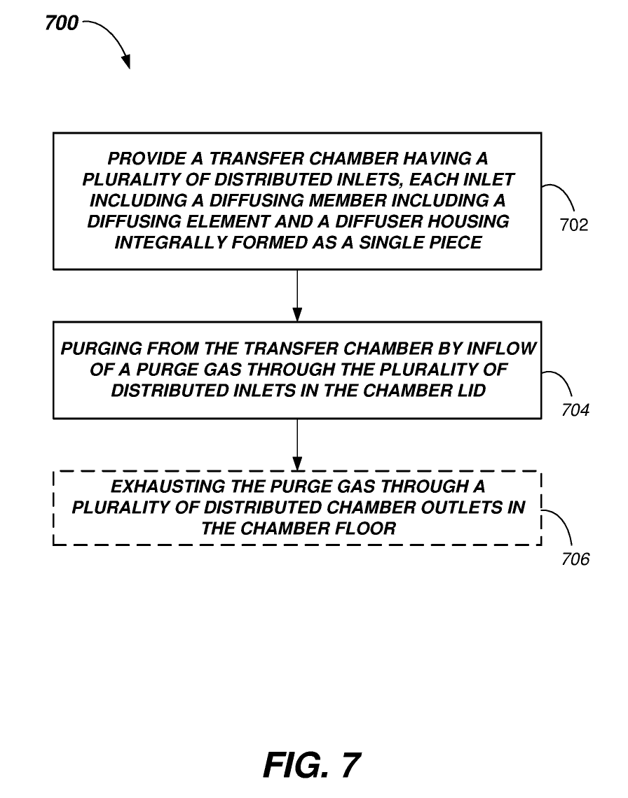

FIG. 7 depicts a flowchart illustrating a method 700 of purging a transfer chamber (e.g., transfer chamber 103) according to one or more embodiments the present invention. The method 700 includes providing a transfer chamber (e.g., transfer chamber 103 at least partially formed by a chamber lid (e.g., chamber lid 106), side walls (e.g., side walls 104), and a chamber floor (e.g., 107), the transfer chamber containing at least a portion of a robot (e.g., robot 112) adapted to transport a substrate (e.g., substrate 114) to and from chambers (e.g., any one or more process chambers 108A-108F or load lock chambers 110A, 110B) accessed from the transfer chamber) having a plurality of inlets, each inlet including a diffusing member including a diffusing element (e.g., diffusing element 230) and a diffuser housing (e.g., diffuser housing 231) integrally formed as a single piece (702).

The method 700 includes in 704, purging from the transfer chamber (e.g., transfer chamber 103) by inflow of a purge gas through the plurality of distributed inlets (e.g., plurality of distributed chamber inlets 116) in the chamber lid (e.g., chamber lid 106).

In one or more embodiments, the purging may further comprise, in 706, exhausting the purge gas through a plurality of distributed chamber outlets (e.g., plurality of distributed chamber outlets 126) provided in the chamber floor (e.g., chamber floor 107). In some embodiments, the purging from the transfer chamber may further comprise inflow of the purge gas through a plurality of diffusing elements (e.g., diffusing elements 230). The purging from the transfer chamber 103 may further comprise providing a substantially laminar flow of the purge gas above the substrate 114 in some embodiments. Purge gas flow conditions to achieve substantially laminar purge gas flow above the substrate 114 may be attained by adjusting the flow control assembly 122 fluidly coupled to the plurality of chamber inlets 116 in the chamber lid 106. Purge gas flow may be additionally controlled by providing the plurality of distributed chamber inlets 116 with primary chamber inlets (e.g., primary chamber inlets 116P) and secondary chamber inlets (e.g., secondary chamber inlets 116S), and independently controlling flow of the purge gas to the primary chamber inlets 116P and the secondary chamber inlets 116S. For example, relatively more purge gas flow may be provided to the primary chamber inlets (e.g., primary inlets 116P) and relatively less flow may be provided to the secondary chamber inlets (e.g., secondary chamber inlets 116S). Further, purge gas flow adjustments may be made in some embodiments to equalize flow patterns within the transfer chamber (e.g., transfer chamber 103).

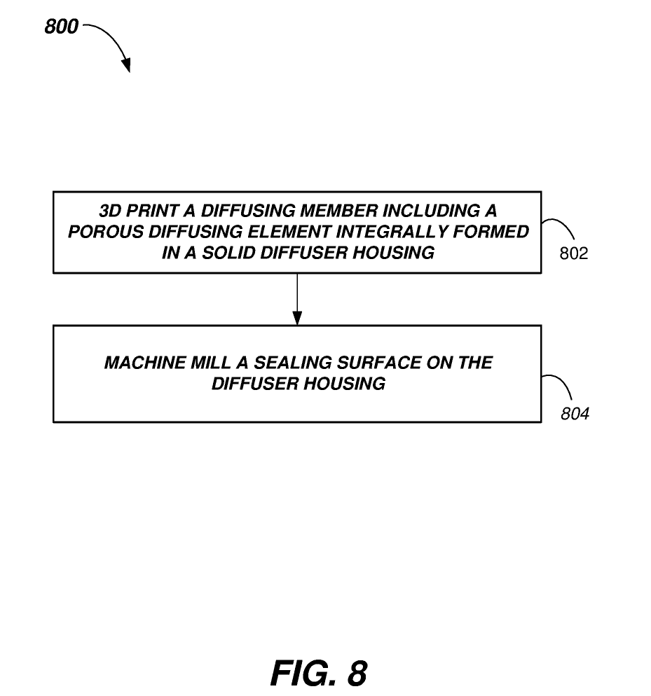

FIG. 8 depicts a flowchart illustrating a first method 800 of manufacturing a diffusing member (e.g., diffusing member 229). The method 800 includes 3D printing a diffusing member including a porous diffusing element integrally formed in a solid diffuser housing (802) and then machine milling a sealing surface on a flange portion of the diffuser housing for sealing the diffusing member to a transfer chamber (804).

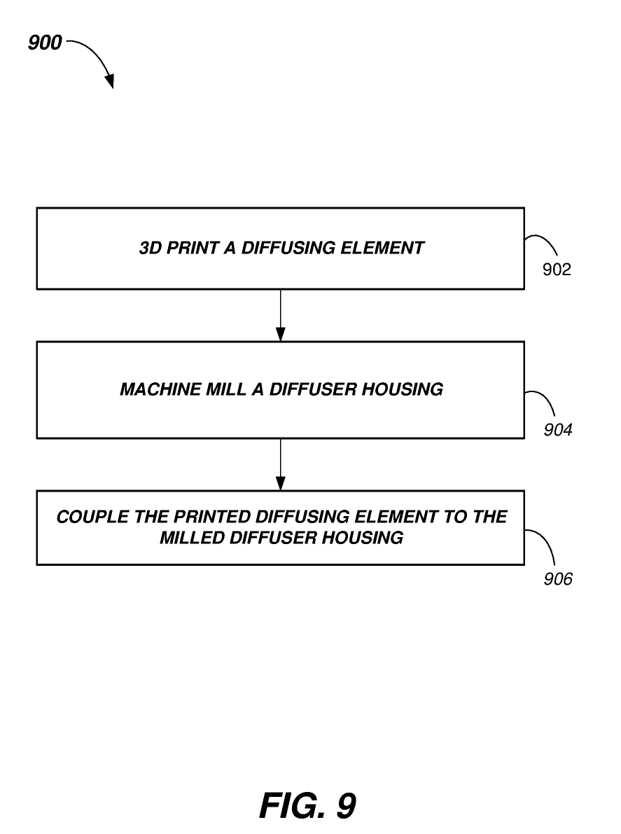

FIG. 9 depicts a flowchart illustrating a second method 900 of manufacturing a diffusing member (e.g., diffusing member 229′). The method 900 includes 3D printing a diffusing element (e.g., diffusing element 230′) (902), milling a diffuser housing (e.g., diffuser housing 231′) (904), and coupling the printed diffusing element to the milled diffuser housing (906).

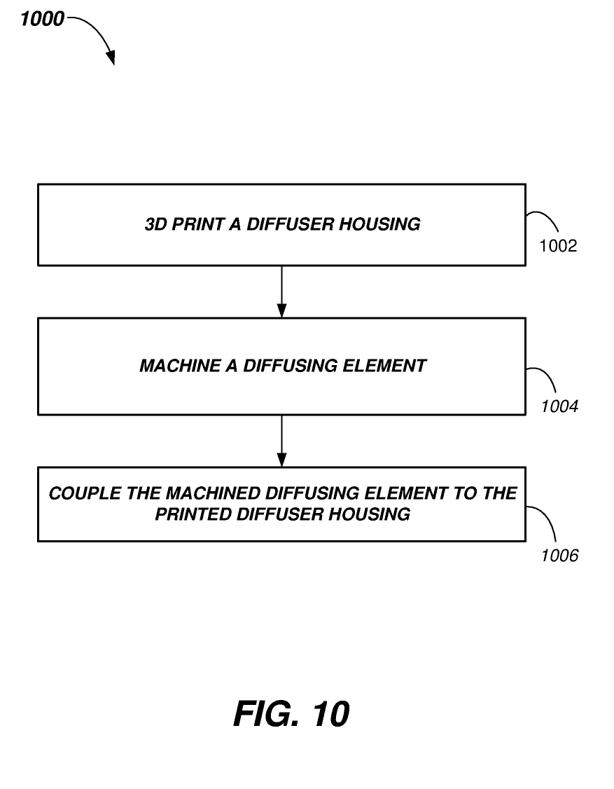

FIG. 10 depicts a flowchart illustrating a third method 1000 of manufacturing a diffusing member (e.g., diffusing member 229″). The method 1000 includes 3D printing a diffuser housing (e.g., diffuser housing 231″) (1002), machining a diffusing element (e.g., diffusing element 230″) (1004), and coupling the printed diffuser housing to the machined diffusing element (1006).

The foregoing description discloses only example embodiments of the invention. Modifications of the above-disclosed apparatus, systems, and methods which fall within the scope of the invention will be readily apparent to those of ordinary skill in the art. Accordingly, while the present invention has been disclosed in connection with example embodiments thereof, it should be understood that other embodiments may fall within the scope of the invention, as defined by the following claims.

The invention claimed is:

1. A transfer chamber gas purge apparatus, comprising:
a transfer chamber including a plurality of distributed purge gas inlets, each inlet including a diffusing member, each diffusing member including a diffusing element and a diffusing housing integrally formed as a single piece.

2. The transfer chamber gas purge apparatus of claim 1, wherein the plurality of distributed chamber inlets include primary chamber inlets and secondary chamber inlets, wherein the primary chamber inlets and secondary chamber inlets are independently controllable and are coupled to a flow control assembly.

3. The transfer chamber purge gas apparatus of claim 1, wherein the diffusing element includes a porous metal disk.

4. The transfer chamber purge gas apparatus of claim 1, wherein the diffusing element includes a porous membrane.

5. The transfer chamber purge gas apparatus of claim 4, wherein the porous membrane is configured to block particles greater than approximately 0.003 microns.

6. The transfer chamber purge gas apparatus of claim 1, wherein the diffuser housing and the diffusing element are formed concurrently via a metal additive manufacturing process.

7. The transfer chamber purge gas apparatus of claim 6, wherein the diffuser housing and the diffusing element are formed with different densities.

8. A diffusing member comprising:
a porous diffusing element; and
a solid diffuser housing,
wherein the solid diffuser housing is integrally formed with the porous diffusing element as a single piece.

9. The diffusing member of claim 8, wherein the diffusing element includes a metal disk.

10. The diffusing member of claim 8, wherein the porous diffusing element and the solid diffuser housing together form a diffusing chamber configured to cause a purge gas exiting the porous diffusing element to have a laminar flow.

11. The diffusing member of claim 10, wherein the porous membrane is configured to block particles greater than approximately 0.003 microns.

12. The diffusing member of claim 8, wherein the diffuser housing and the diffusing element are formed concurrently via a metal additive manufacturing process.

13. The diffusing member of claim 8, wherein the diffuser housing and the diffusing element are formed with different densities.

14. A method of purging a transfer chamber, the method comprising:
providing a transfer chamber having a plurality of distributed purge gas inlets, each inlet including a diffusing member, each diffusing member including a diffusing element and a diffusing housing integrally formed as a single piece; and
purging from the transfer chamber by inflow of a purge gas through the plurality of distributed purge gas inlets.

15. The method of claim 14, wherein providing a transfer chamber includes providing the diffusing element in the form of a metal disk.

16. The method of claim 14, wherein the porous diffusing element and the solid diffuser housing together form a diffusing chamber configured to cause a purge gas exiting the porous diffusing element to have a laminar flow.

17. The method of claim 16, wherein the porous membrane is configured to block particles greater than approximately 0.003 microns.

18. The method of claim 14, wherein the diffuser housing and the diffusing element are formed concurrently via a metal additive manufacturing process.

19. The method of claim 14, wherein the diffuser housing and the diffusing element are formed with different densities.

20. The method of claim 14, wherein purging from the transfer chamber includes providing a non-turbulent flow of gas through the diffusing member.
